(19) United States
(12) Patent Application Publication
(10) Pub. No.: US 2005/0285186 A1
(43) Pub. Date: Dec. 29, 2005

(54) Semiconductor device and method of fabricating the same

(75) Inventor: Makoto Fujiwara, Kanagawa (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/057,366

(22) Filed: Feb. 15, 2005

(30) Foreign Application Priority Data
Jun. 29, 2004 (JP) 2004-191117

(51) Int. Cl. H01L 29/80

(52) U.S. Cl. 257/327

(57) ABSTRACT

According to the present invention, there is provided a semiconductor device comprising: a semiconductor layer formed on a semiconductor substrate via a first insulating film and having a projecting shape; a second insulating film formed on said first insulating film, and having a film thickness by which said semiconductor layer is buried from a bottom portion thereof to a predetermined height; a gate electrode formed, via a gate insulating film, on side surfaces, which are formed substantially parallel to a direction of an electric current flowing in a channel region, of said semiconductor layer; and a source region and drain region formed in a region, in which said gate electrode is not formed, of said semiconductor layer.

### CROSS REFERENCE TO RELATED APPLICATION

This application is based upon and claims benefit of priority under 35 USC §119 from the Japanese Patent Application No. 2004-191117, filed on Jun. 29, 2004, the entire contents of which are incorporated herein by reference.

### BACKGROUND OF THE INVENTION

The present invention relates to a semiconductor device and a method of fabricating the same.

Recently, to meet demands for low power consumption and high operating speed, semiconductor integrated circuits are required to lower the power supply voltage and increase the degree of micropatterning of elements. Therefore, elements having three-dimensional structures are developed. Compared to the conventional planar type elements, these three-dimensional elements have advantages such as suppression of the short channel effect, a low subthreshold slope (excellent switching characteristics), and high mobility.

As such three-dimensional elements, so-called double-gate-structure MISFETs (Metal Insulator Semiconductor Field Effect Transistors) are developed. In particular, a MISFET having a fin-shaped semiconductor layer is called a FinFET.

In this FinFET, a semiconductor layer having a projecting shape is formed on a semiconductor substrate via a buried insulating film. On two side surfaces of this semiconductor layer, a gate electrode is formed to cross the semiconductor layer.

Also, in the FinFET, a channel region is formed in that region of the semiconductor layer, which is surrounded by the gate electrode. In addition, on the two sides of this channel region in the semiconductor layer, a source region and drain region are so formed as to sandwich the channel region.

In the fabrication process of the FinFET, a semiconductor layer stacked on a semiconductor substrate via a buried insulating film is etched into a projecting semiconductor layer, and then wet etching is performed as a cleaning process.

This wet etching is isotropic etching by which etching equally progresses in all directions. Therefore, an etching solution flows to the periphery of the bottom portion of the projecting semiconductor layer. As a consequence, etching progresses not only in the vertical of depth but also in the lateral direction of the buried insulating film.

Accordingly, if a gate electrode is formed by depositing a gate electrode material after wet etching, this gate electrode material is deposited in the etched region around the bottom portion of the semiconductor layer, and forms a gate electrode in this region.

In a FinFET thus fabricated, an electric field from the gate electrode concentrates to the corners and their vicinities of the bottom portion of the semiconductor layer. This poses the problem of a parasitic transistor operation in the corners and their vicinities. Also, in this FinFET, the gate electrode is in contact with the source and drain regions formed in the semiconductor layer via the gate insulating film. This increases the leakage current and capacitance between the gate electrode and the source and drain regions.

A reference concerning the FinFET fabrication method is as follows.
Patent reference 1: Japanese Patent Laid-Open No. 2001-77364

### SUMMARY OF THE INVENTION

According to one aspect of the present invention, there is provided a semiconductor device fabrication method, comprising:

depositing a mask material on a semiconductor layer formed on a semiconductor substrate via a first insulating film;

forming a semiconductor layer having a projecting shape by patterning the semiconductor layer and mask material;

depositing a second insulating film on the first insulating film and mask material, and etching back the second insulating film by using the mask material as a mask, thereby forming a second insulating film having a film thickness by which the semiconductor layer is buried from a bottom portion thereof to a predetermined height;

forming a gate insulating film on side surfaces, which are formed substantially parallel to a direction of an electric current flowing in a channel region, of the semiconductor layer;

depositing a gate electrode material on the insulating film, and patterning the gate electrode material, thereby forming a gate electrode, via the gate insulating film, on the side surfaces, which are formed substantially parallel to the direction of the electric current flowing in the channel region, of the semiconductor layer; and

ion-implanting a predetermined impurity into the semiconductor layer by using the gate electrode as a mask, thereby forming a source region and drain region in a region, in which the gate electrode is not formed, of the semiconductor layer.

According to one aspect of the present invention, there is provided a semiconductor device comprising:

a semiconductor layer formed on a semiconductor substrate via a first insulating film and having a projecting shape;

a second insulating film formed on said first insulating film, and having a film thickness by which said semiconductor layer is buried from a bottom portion thereof to a predetermined height;

a gate electrode formed, via a gate insulating film, on side surfaces, which are formed substantially parallel to a direction of an electric current flowing in a channel region, of said semiconductor layer; and

a source region and drain region formed in a region, in which said gate electrode is not formed, of said semiconductor layer.

### BRIEF DESCRIPTION OF THE DRAWINGS

FIG. 1 is a longitudinal sectional view showing the sectional structure of an element in a step of a method of fabricating a FinFET according to an embodiment of the present invention;

FIG. 2 is a perspective view of the element in another step of the method of fabricating the FinFET;

FIG. 3 is a longitudinal sectional view showing the sectional structure of the element in still another step of the method of fabricating the FinFET;

FIG. 4 is a longitudinal sectional view showing the sectional structure of the element in still another step of the method of fabricating the FinFET;

FIG. 5 is a longitudinal sectional view showing the sectional structure of the element in still another step of the method of fabricating the FinFET;

FIG. 6 is a longitudinal sectional view showing the sectional structure of the element in still another step of the method of fabricating the FinFET;

FIG. 7 is a longitudinal sectional view showing the sectional structure of the element in still another step of the method of fabricating the FinFET;

FIG. 8 is a longitudinal sectional view showing the sectional structure of the element in still another step of the method of fabricating the FinFET;

FIG. 9 is a longitudinal sectional view showing the sectional structure of the element in still another step of the method of fabricating the FinFET;

FIG. 10 is a longitudinal sectional view showing the sectional structure of the element in still another step of the method of fabricating the FinFET;

FIG. 11 is a longitudinal sectional view showing the sectional structure of the element in still another step of the method of fabricating the FinFET;

FIG. 12 is a cross-sectional view showing the sectional structure of the element in still another step of the method of fabricating the FinFET.

### DETAILED DESCRIPTION OF THE EMBODIMENTS

An embodiment of the present invention will be described below with reference to the accompanying drawings.

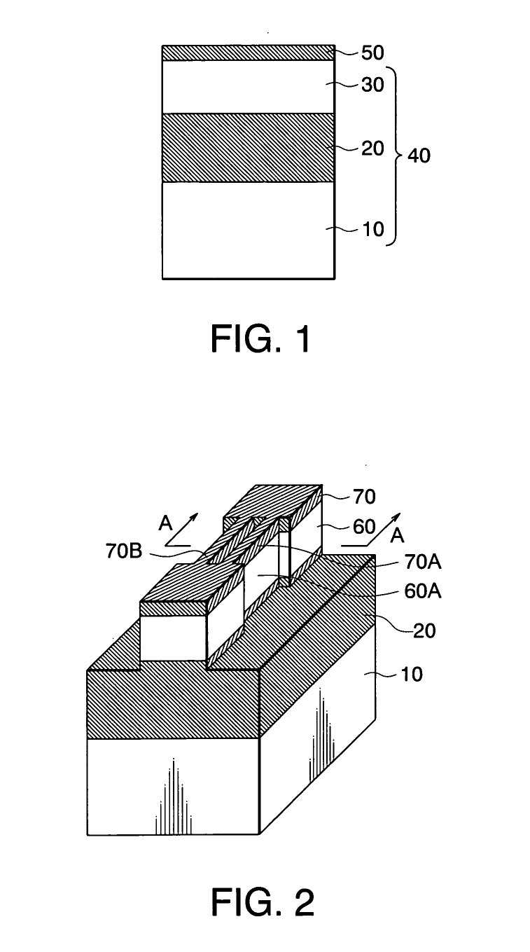

FIGS. 1 to 12 illustrate a method of fabricating a FinFET according to the embodiment of the present invention. First, an SOI (Silicon On Insulator) substrate 40 is prepared by stacking a buried insulating film 20 and semiconductor layer 30 in this order on a semiconductor substrate 10. Note that the semiconductor substrate 10 and semiconductor layer 30 are made of, e.g., single-crystal silicon.

As shown in FIG. 1, a mask material 50 having a stacked structure of, e.g., a silicon oxide film and silicon nitride film is deposited on the SOI substrate 40 by CVD (Chemical Vapor Deposition) or the like.

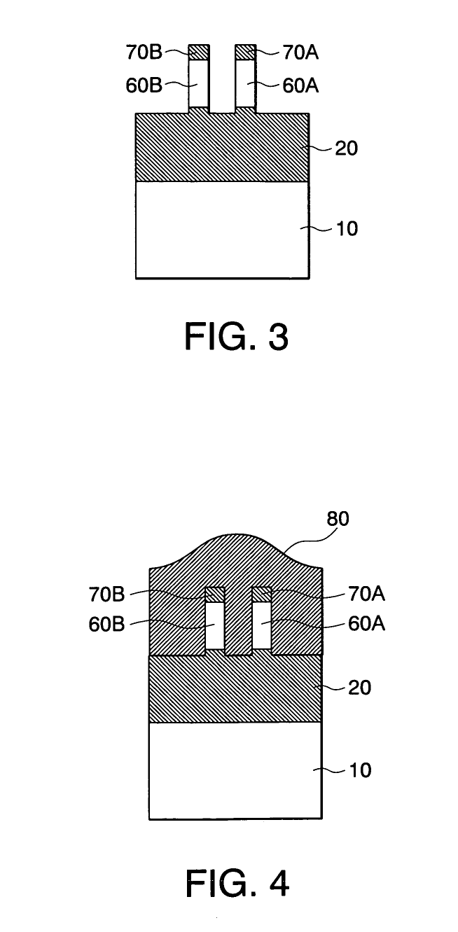

As shown in FIG. 2 and FIG. 3 as a longitudinal sectional view taken along a line A-A in FIG. 2, lithography and RIE (Reactive Ion Etching) are used to pattern the mask material 50 and semiconductor layer 30 in this order, thereby forming a projecting semiconductor layer 60 and mask material 70 on the buried insulating film 20, and forming two fins 60A and 60B in the semiconductor layer 60.

In this embodiment, when the semiconductor layer 30 is etched, the upper portion of the buried insulating film 20 is slightly etched by overetching. However, just etching may also be used.

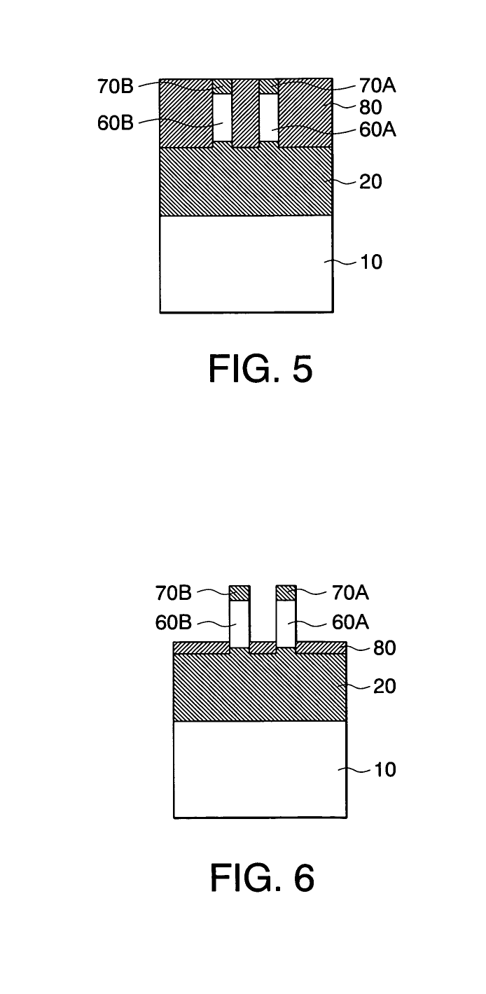

As shown in FIG. 4, an insulating film 80 made of, e.g., a silicon oxide film is deposited by CVD or the like. As shown in FIG. 5, the mask material 70 is used as a stopper to planarize the insulating film 80 by CMP (Chemical Mechanical Polishing).

As shown in FIG. 6, the insulating film 80 is selectively etched back to a desired film thickness, thereby exposing the upper portion of the semiconductor layer 60.

The film thickness of the insulating film 80 is about ⅕ the height of the semiconductor layer 60. For example, when the height of the semiconductor layer 60 is about 100 nm, the film thickness of the insulating film 80 is 20 to 30 nm. Note that the film thickness of the insulating film 80 is larger than at least the amount of overetching of the buried insulating film 20.

After that, wet etching is performed as a cleaning process. In this embodiment, the insulating film 80 is formed near the lower portion of the semiconductor layer 60. Therefore, even when isotropic wet etching is performed, an etching solution does not flow to the bottom portion of the semiconductor layer 60, although the insulating film 80 is slightly etched. Accordingly, even when a gate electrode material is deposited after wet etching, it is possible to avoid this gate electrode material from being deposited in a region around the bottom portion of the semiconductor layer 60.

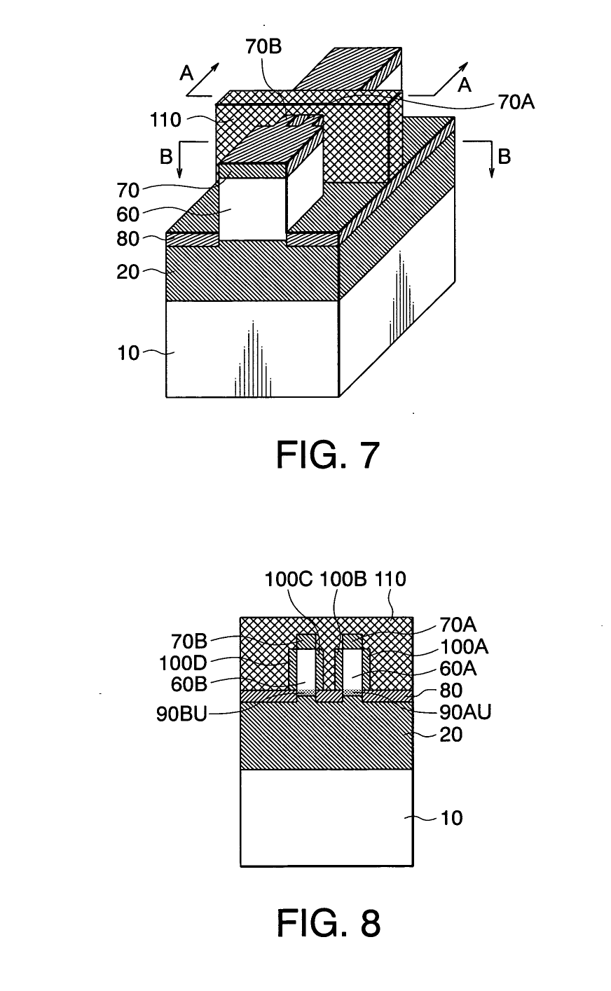

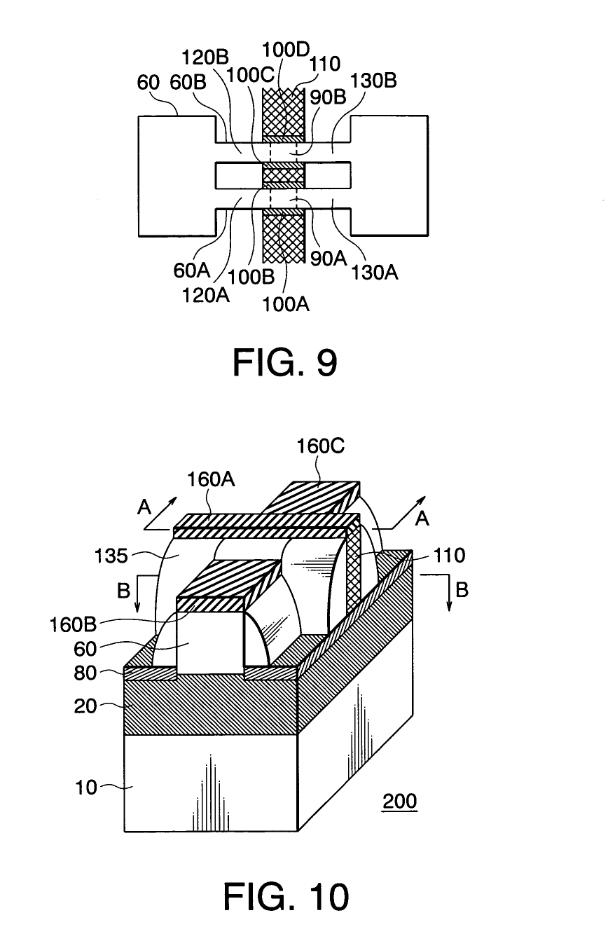

As shown in FIG. 7, FIG. 8 as a longitudinal sectional view taken along a line A-A in FIG. 7, and FIG. 9 as a cross-sectional view taken along a line B-B in FIG. 7, an impurity such as arsenic, boron, indium, or phosphorus is ion-implanted into lower portions of those regions of the semiconductor layer 60, which function as channel regions 90A and 90B, thereby increasing the impurity concentration in lower regions 90AU and 90BU, which are surrounded by the insulating film 80, of the channel regions 90A and 90B.

Of the channel regions 90A and 90B, the lower regions 90AU and 90BU surrounded by the insulating film 80 are apart from a gate electrode 110 to be formed later. Therefore, the control of the gate electrode 110 is weak, so punch-through readily occurs. However, this punch-through can be suppressed by increasing the impurity concentration.

Gate insulating films 100A to 100D having a desired film thickness are formed on those side surfaces of the fins 60A and 60B of the semiconductor layer 60, which are close to the channel regions 90A and 90B. The film thickness of the gate insulating films 100A to 100D is 1 to 5 nm.

A polysilicon film as a gate electrode material is deposited by CVD or the like, planarized by CMP, and patterned by lithography and RIE, thereby forming a gate electrode 110.

Note that a metal may also be used as a gate electrode material. In this case, the driving current can be increased since no depletion occurs in the gate electrode.

An impurity having a conductivity type opposite to that of the semiconductor layer 60 is obliquely ion-implanted into the semiconductor layer 60 by using the gate electrode 110 as a mask. In this way, a source extension region 120A and drain extension region 130A are formed on the two sides of the channel region 90A of the fin 60A of the semiconductor layer 60. In addition, a source extension region 120B and drain extension region 130B are formed on the two sides of the channel region 90B of the fin 60B of the semiconductor layer 60.

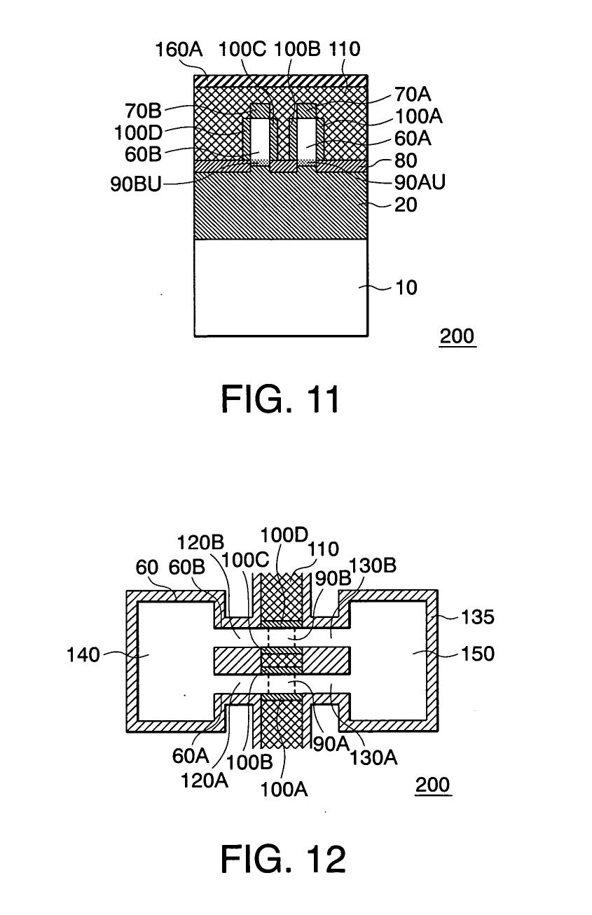

As shown in FIG. 10, FIG. 11 as a longitudinal sectional view taken along a line A-A in FIG. 10, and FIG. 12 as a cross-sectional view taken along a line B-B in FIG. 10, after an insulating film made of, e.g., a silicon nitride film is deposited, a sidewall insulating film 135 is formed on the side surfaces of the gate electrode 110 and semiconductor layer 60 by RIE. Also, the mask material 70 formed on those regions of the semiconductor layer 60, which function as a source region 140 and drain region 150 is removed.

The source region 140 and drain region 150 are formed by ion-implanting a predetermined impurity into the semiconductor layer 60 by using the gate electrode 110 and sidewall insulating film 135 as masks. A metal film made of, e.g., nickel (Ni), cobalt (Co), or titanium (Ti) is deposited and annealed to form metal silicide films 160A to 160C for reducing the parasitic resistance in the surface portions of the gate electrode 110 and the source region 140 and drain region 150 of the semiconductor layer 60. After that, wiring is formed by sequentially forming an interlayer dielectric film and contact plug (not shown), thereby fabricating a FinFET 200.

In the FinFET 200 fabricated by the above method, as shown in FIGS. 10, 11, and 12, the buried insulating film 20 is formed on the surface of the semiconductor substrate 10. On the buried insulating film 20, the semiconductor layer 60 having the two fines 60A and 60B is formed, and the insulating film 80 is formed to bury the lower portion of the semiconductor layer 60.

The channel regions 90A and 90B are formed in the central portions of the fins 60A and 60B, respectively, of the semiconductor layer 60. An impurity is doped into the lower regions 90AU and 90BU, which are surrounded by the insulating film 80, of the channel regions 90A and 90B, respectively, thereby increasing the impurity concentration in these regions.

The channel regions 90A and 90B have a small width (the spacing between the gate insulating films 100A and 100B (100C and 100D)) by which the channel regions 90A and 90B operate as completely depleted elements. More specifically, a width W_{Fin} of the channel regions 90A and 90B is made smaller than a gate length Lg. This realizes the FinFET 200 having a low subthreshold coefficient, high mobility, and a low junction leakage current.

In the fin 60A of the semiconductor layer 60, the source extension region 120A and drain extension region 130A are formed on the two sides of the channel region 90A so as to sandwich the channel region 90A. Also, in the fin 60B of the semiconductor layer 60, the source extension region 120B and drain extension region 130B are formed on the two sides of the channel region 90B so as to sandwich the channel region 90B.

Furthermore, in the semiconductor layer 60, the source region 140 and drain region 150 are so formed as to sandwich the fins 60A and 60B. The source region 140 is adjacent to the source extension regions 120A and 120B. The drain region 150 is adjacent to the drain extension regions 130A and 130B.

The gate insulating films 100A to 100D are formed on the side surfaces near the channel regions 90A and 90B of the fins 60A and 60B of the semiconductor layer 60. The mask materials 70A and 70B are formed on the upper surfaces of the fins 60A and 60B, respectively.

The film thickness of the mask materials 70A and 70B is made larger than that of the gate insulating films 100A to 100D. Accordingly, that upper surface of the semiconductor layer 60, which is adjacent to the mask materials 70A and 70B is always OFF and hence does not function as a channel. This prevents a parasitic transistor operation at the corners of the channel regions 90A and 90B of the fins 60A and 60B, respectively. Also, the mask materials 70A and 70B function as stoppers and are slightly etched when the insulating film 80 is planarized by CMP. Therefore, the film thickness must be set by taking this etching amount into account.

The gate electrode 110 is formed on the side surfaces and upper surfaces of the fins 60A and 60B via the gate insulating films 100A to 100D and mask materials 70A and 70B, so as to cross the fins 60A and 60B.

The sidewall insulating film 135 is formed on the side surfaces of the gate electrode 110 and semiconductor layer 60. In addition, the metal silicide films 160A to 160C are formed in the surface portions of the gate electrode 110 and the source region 140 and drain region 150 of the semiconductor layer 60.

In this embodiment as described above, before wet etching as a cleaning process is performed, the insulating film 80 having a film thickness by which the lower portion of the semiconductor layer 60 is buried is formed. Therefore, even when wet etching is performed, no etching solution flows to the bottom portion of the semiconductor layer 60, although the insulating film 80 is slightly etched.

Accordingly, even when a gate electrode material is deposited to form the gate electrode 110 after wet etching, it is possible to avoid the gate electrode material from being deposited in a region around the bottom portion of the semiconductor layer 60. This makes it possible to prevent a parasitic transistor operation at the corners of the bottom portion of the semiconductor layer 60, and prevent the increase in leakage current and capacitance between the gate electrode 110 and the source region 140 and drain region 150.

Note that the above embodiment is merely an example, and hence does not limit the present invention. For example, the number of the fins formed in the semiconductor layer 60 need not be two. That is, it is also possible to form only one fin or three or more fins.

In the above embodiment, the inverted U-shaped gate electrode 110 is formed on those side surfaces and upper surfaces of the fins 60A and 60B of the semiconductor layer 60, which are close to the channel regions 90A and 90B, so as to cross the semiconductor layer 60. However, the present invention is not limited to this structure. For example, if only one fin is formed, it is also possible to form separate gate electrodes only on the side surfaces of the semiconductor layer 60, without forming any gate electrode on the upper surface of the semiconductor layer 60. In this structure, different voltages can be applied to the two gate electrodes on the two sides of the fin, and the threshold voltage can be adjusted by the voltage applied to one gate electrode.

In the above embodiment, the channel regions 90A and 90B and the source region 140 and drain region 150 of the silicon layer 60 are formed at the same height. However, the present invention is not limited to this structure. That is, it is also possible to perform epitaxial growth after the sidewall insulating film 135 is formed and the mask material 70 is removed, thereby making the source region 140 and drain region 150 higher than the channel regions 90A and 90B. In this structure, the parasitic resistance in the source region 140 and drain region 150 can be reduced.

As described above, the semiconductor device and the method of fabricating the same according to the above embodiment can prevent a parasitic transistor operation, and prevent the increase in leakage current and capacitance between the gate electrode and the source and drain regions.

1. A semiconductor device fabrication method, comprising:
depositing a mask material on a semiconductor layer formed on a semiconductor substrate via a first insulating film;
forming a semiconductor layer having a projecting shape by patterning the semiconductor layer and mask material;
depositing a second insulating film on the first insulating film and mask material, and etching back the second insulating film by using the mask material as a mask, thereby forming a second insulating film having a film thickness by which the semiconductor layer is buried from a bottom portion thereof to a predetermined height;
forming a gate insulating film on side surfaces, which are formed substantially parallel to a direction of an electric current flowing in a channel region, of the semiconductor layer;
depositing a gate electrode material on the insulating film, and patterning the gate electrode material, thereby forming a gate electrode, via the gate insulating film, on the side surfaces, which are formed substantially parallel to the direction of the electric current flowing in the channel region, of the semiconductor layer; and
ion-implanting a predetermined impurity into the semiconductor layer by using the gate electrode as a mask, thereby forming a source region and drain region in a region, in which the gate electrode is not formed, of the semiconductor layer.

2. A method according to claim 1, further comprising, ion-implanting a predetermined impurity into a lower portion of the channel region formed in the semiconductor layer, thereby making an impurity concentration in a lower portion, which is surrounded by the second insulating film, of the channel region higher than that in another portion.

3. A method according to claim 1, wherein the second insulating film is formed to have a film thickness substantially ⅕ a height of the semiconductor layer.

4. A method according to claim 1, wherein the second insulating film is formed to have a film thickness larger than an etching amount of the isotropic etching.

5. A method according to claim 1, wherein the second insulating film is formed to have a film thickness larger than an etching amount of overetching of the first insulating film when the semiconductor layer having a projecting shape is formed.

6. A method according to claim 3, wherein the second insulating film is formed to have a film thickness of 20 to 30 nm when the height of the semiconductor layer is about 100 nm.

7. A method according to claim 1, wherein wet etching is performed as a cleaning process.

8. A method according to claim 1, wherein when the gate electrode is formed, a gate electrode material is deposited on the second insulating film, gate insulating film, and mask material, and patterned to form, across the semiconductor layer, the gate electrode having an inverted U-shape on side surfaces and an upper surface of the semiconductor layer via the gate insulating film and mask material.

9. A method according to claim 1, wherein the gate insulating film is formed to have a film thickness of 1 to 5 nm when a height of the semiconductor layer is about 100 nm.

10. A semiconductor device comprising:
a semiconductor layer formed on a semiconductor substrate via a first insulating film and having a projecting shape;
a second insulating film formed on said first insulating film, and having a film thickness by which said semiconductor layer is buried from a bottom portion thereof to a predetermined height;
a gate electrode formed, via a gate insulating film, on side surfaces, which are formed substantially parallel to a direction of an electric current flowing in a channel region, of said semiconductor layer; and
a source region and drain region formed in a region, in which said gate electrode is not formed, of said semiconductor layer.

11. A device according to claim 10, wherein an impurity concentration in a lower portion, which is surrounded by said second insulating film, of said channel region is higher than that in another portion.

12. A device according to claim 10, wherein a film thickness of said second insulating film is substantially ⅕ a height of said semiconductor layer.

13. A device according to claim 12, wherein the film thickness of said second insulating film is 20 to 30 nm when the height of said semiconductor layer is about 100 nm.

14. A device according to claim 10, wherein the gate electrode is formed on the side surfaces and upper surface of said semiconductor layer via said gate insulating film and mask material, and has an inverted U-shape so as to cross said semiconductor layer.

15. A device according to claim 14, wherein said mask material is formed to have a film thickness larger than that of said gate insulating film.

16. A device according to claim 10, wherein a film thickness of said gate insulating film is 1 to 5 nm when a height of said semiconductor layer is about 100 nm.

17. A device according to claim 10, wherein different voltages are applied to said gate electrode formed on the side surfaces of said semiconductor layer via said gate insulating film.

18. A device according to claim 10, wherein a width of said semiconductor layer in said channel region is smaller than a gate length of said gate electrode.

19. A device according to claim 10, wherein said source region and drain region are higher than said channel region.

20. A device according to claim 10, further comprising a metal silicide film formed in surface portions of said source region and drain region, wherein said gate electrode is made of a metal film.
